(19) United States
(12) Patent Application Publication
(10) Pub. No.: US 2024/0194261 A1
(43) Pub. Date: Jun. 13, 2024

(54) SEMICONDUCTOR MEMORY DEVICE

(71) Applicant: SK hynix Inc., Icheon-si Gyeonggi-do (KR)

(72) Inventor: Eun Seok CHOI, Icheon-si Gyeonggi-do (KR)

(73) Assignee: SK hynix Inc., Icheon-si Gyeonggi-do (KR)

(21) Appl. No.: 18/331,821

(22) Filed: Jun. 8, 2023

(30) Foreign Application Priority Data
Dec. 7, 2022 (KR) 10-2022-0169459

(51) Int. Cl. G11C 16/04; H01L 23/00; H01L 23/522; H01L 23/528; H10B 41/10; H10B 41/27; H10B 41/40; H10B 43/10; H10B 43/27; H10B 43/40

(52) U.S. Cl. CPC G11C 16/0483; H01L 23/5226; H01L 23/5283; H01L 24/05; H10B 41/10; H10B 41/27; H10B 41/40; H10B 43/10; H10B 43/27; H10B 43/40; H01L 2224/0557; H01L 2224/05647

(57) ABSTRACT

A semiconductor memory device includes a source bonding structure including a first source layer and a second source layer bonded to each other, a first memory cell array structure connected to the first source layer of the source bonding structure, and a second memory cell array structure connected to the second source layer of the source bonding structure. The source bonding structure includes at least one of a semiconductor bonding area and a metal bonding area.

### CROSS-REFERENCE TO RELATED APPLICATION

The present application claims priority under 35 U.S.C. § 119(a) to Korean patent application number 10-2022-0169459 filed on Dec. 7, 2022, in the Korean Intellectual Property Office, the entire disclosure of which is incorporated by reference herein.

### BACKGROUND

### 1. Technical Field

The present disclosure relates to an electronic device, and more particularly, to a semiconductor memory device.

### 2. Related Art

A semiconductor memory device may be applied to electronic devices of various fields, such as an automobile, a medical care, and a data center, as well as a small electronic device, and demand for the semiconductor memory device is increasing.

An electronic device may include a semiconductor memory device configuring a storage device. The semiconductor memory device may include a plurality of memory cells. Various technologies for improving an integration degree of the plurality of memory cells are being developed.

### SUMMARY

According to an embodiment of the present disclosure, a semiconductor memory device may include a source bonding structure including a first source layer and a second source layer bonded to each other, a first memory cell array structure connected to the first source layer of the source bonding structure, and a second memory cell array structure connected to the second source layer of the source bonding structure, and the source bonding structure may include a semiconductor bonding area and a metal bonding area.

### BRIEF DESCRIPTION OF THE DRAWINGS

FIG. 1 is a block diagram illustrating a semiconductor memory device according to an embodiment of the present disclosure.

FIG. 2 is a circuit diagram of a memory cell array according to an embodiment of the present disclosure.

FIGS. 3A and 3B are diagrams illustrating a semiconductor memory device according to an embodiment of the present disclosure.

FIGS. 4A, 4B, 4C, and 4D are cross-sectional views illustrating the semiconductor memory device shown in FIG. 3B.

FIGS. 5A and 5B are diagrams illustrating a partial configuration of the semiconductor memory device described with reference to FIGS. 3A, 3B, and 4A to 4D.

FIG. 6 is a flowchart illustrating a method of manufacturing a semiconductor memory device according to an embodiment of the present disclosure.

FIGS. 7A and 7B are diagrams illustrating a semiconductor memory device according to an embodiment of the present disclosure.

FIG. 8 is a flowchart illustrating a method of manufacturing a semiconductor memory device according to an embodiment of the present disclosure.

FIGS. 9A and 9B are diagrams illustrating a semiconductor memory device according to an embodiment of the present disclosure.

FIG. 10 is a flowchart illustrating a method of manufacturing a semiconductor memory device according to an embodiment of the present disclosure.

FIGS. 11A and 11B are cross-sectional views illustrating a source bonding structure and a pad bonding structure according to embodiments of the present disclosure.

FIG. 12 is a block diagram illustrating an electronic system including a semiconductor memory device according to embodiments of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present.

Various embodiments of the present disclosure are directed to a semiconductor memory device capable of improving an integration degree.

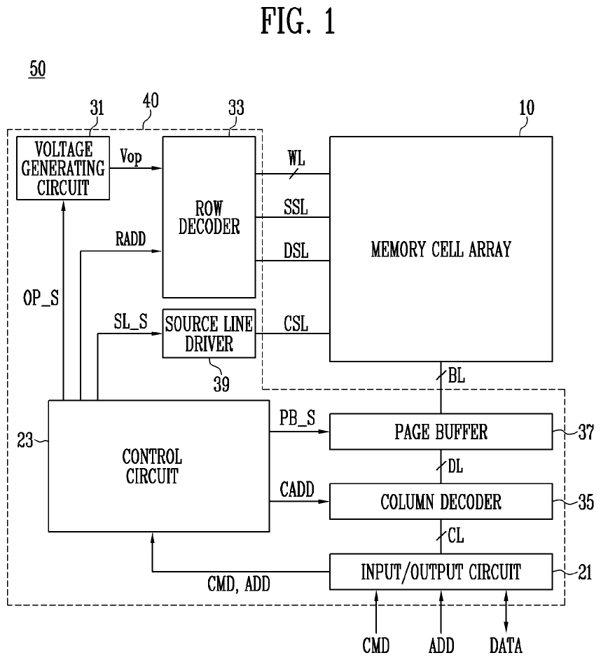

FIG. 1 is a block diagram illustrating a semiconductor memory device according to an embodiment of the present disclosure.

Referring to FIG. 1, the semiconductor memory device 50 may include a peripheral circuit 40 and a memory cell array 10.

The peripheral circuit 40 may be configured to perform a program operation for storing data in the memory cell array 10, a read operation for outputting data stored in the memory cell array 10, and an erase operation for erasing data stored in the memory cell array 10. As an embodiment, the peripheral circuit 40 may include an input/output circuit 21, a control circuit 23, a voltage generating circuit 31, a row decoder 33, a column decoder 35, a page buffer 37, and a source line driver 39.

The peripheral circuit 40 may be connected to the memory cell array 10 through a common source line CSL, a bit line BL, a drain select line DSL, a word line WL, and a source select line SSL.

The input/output circuit 21 may transmit a command CMD and an address ADD received from an external device (for example, a memory controller) of the semiconductor memory device 50 to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operation voltages Vop used for the program operation, the read operation, and the erase operation in response to the operation signal OP_S.

The row decoder 33 may transmit the operation voltages Vop to the drain select line DSL, the word line WL, and the source select line SSL in response to the row address RADD.

The column decoder 35 may transmit the data DATA input from the input/output circuit 21 to the page buffer 37 or transmit the data DATA stored in the page buffer 37 to the input/output circuit 21, in response to the column address CADD. The column decoder 35 may exchange the data DATA with the input/output circuit 21 through a column line CL. The column decoder 35 may exchange the data DATA with the page buffer 37 through a data line DL.

The page buffer 37 may store read data received through the bit line BL in response to the page buffer control signal PB_S. The page buffer 37 may sense a voltage or a current of the bit line BL during the read operation.

The source line driver 39 may control a voltage applied to the common source line CSL in response to the source line control signal SL_S.

The memory cell array 10 may include a plurality of memory blocks. Each of the memory blocks may include a plurality of memory cells. Each of the memory cells may be a nonvolatile memory cell. As an embodiment, each of the memory cells may be a NAND flash memory cell.

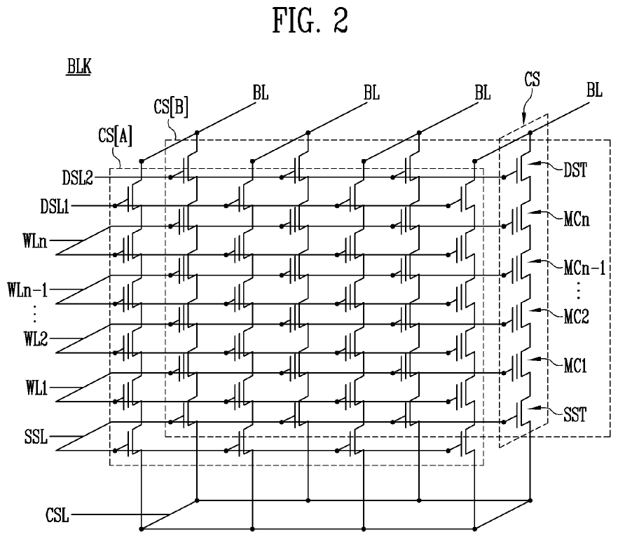

FIG. 2 is a circuit diagram of a memory cell array according to an embodiment of the present disclosure.

Referring to FIG. 2, the memory cell array may include a memory block BLK. The memory block BLK may include a plurality of memory cell strings CS.

Each memory cell string CS may include at least one source select transistor SST, a plurality of memory cells MC1 to MCn, and at least one drain select transistor DST. The plurality of memory cells MC1 to MCn may be connected in series between the source select transistor SST and the drain select transistor DST. The source select transistor SST, the plurality of memory cells MC1 to MCn, and the drain select transistor DST may be connected in series by a channel layer.

The plurality of memory cell strings CS may be connected in parallel to the common source line CSL. Each memory cell string CS may be connected to a bit line corresponding thereto among a plurality of bit lines BL. The common source line CSL and the plurality of bit lines BL may be connected to a plurality of channel layers of the plurality of cell strings CS.

The plurality of memory cells MC1 to MCn of the memory cell string CS may be connected to the common source line CSL via the source select transistor SST. The plurality of memory cells MC1 to MCn of the memory cell string CS may be connected to a bit line BL corresponding thereto via the drain select transistor DST.

The memory cell string CS may be connected to the source select line SSL, a plurality of word lines WL1 to WLn, and a drain select line DSL1 or DSL2. The source select line SSL may serve as a gate electrode of the source select transistor SST. The plurality of word lines WL1 to WLn may serve as gate electrodes of the plurality of memory cells MC1 to MCn. The drain select line DSL1 or DSL2 may serve as a gate electrode of the drain select transistor DST.

Each word line of the plurality of word lines WL1 to WLn may control the plurality of memory cell strings CS. The plurality of memory cell strings CS may be divided into two or more string groups. Each bit line BL may be connected to different string groups. As an embodiment, a first memory cell string of a first string group CS[A] and a second memory cell string of a second string group CS[B] may be connected to each bit line BL. The first string group CS[A] and the second string group CS[B] may be individually controlled by drain select lines separated from each other or source select lines separated from each other. As an embodiment, the first string group CS[A] may be connected to the first drain select line DSL1, and the second string group CS[B] may be connected to the second drain select line DSL2. At this time, the first string group CS[A] and the second string group CS[B] may be connected to the same source select line SSL. An embodiment of the present disclosure is not limited thereto. Although not shown in the drawing, as an embodiment, the first memory cell string of the first string group CS[A] and the second memory cell string of the second string group CS[B] connected to the same bit line BL may be connected to the same drain select line, and may be respectively connected to first and second source select lines separated from each other. Although not shown in the drawing, as an embodiment, the first memory cell string of the first string group CS[A] and the second memory cell string of the second string group CS[B] connected to the same bit line BL may be respectively connected to the first and second drain select lines separated from each other, and may be respectively connected to the first and second source select lines separated from each other.

Each bit line BL may be connected to a channel layer of a memory cell string CS corresponding thereto. An operation voltage for precharging the channel layer of the memory cell string CS may be applied to the bit line BL.

The common source line CSL may be connected to the channel layer of the memory cell string CS. An operating voltage for discharging the channel potential of the memory cell string CS may be applied to the common source line CSL.

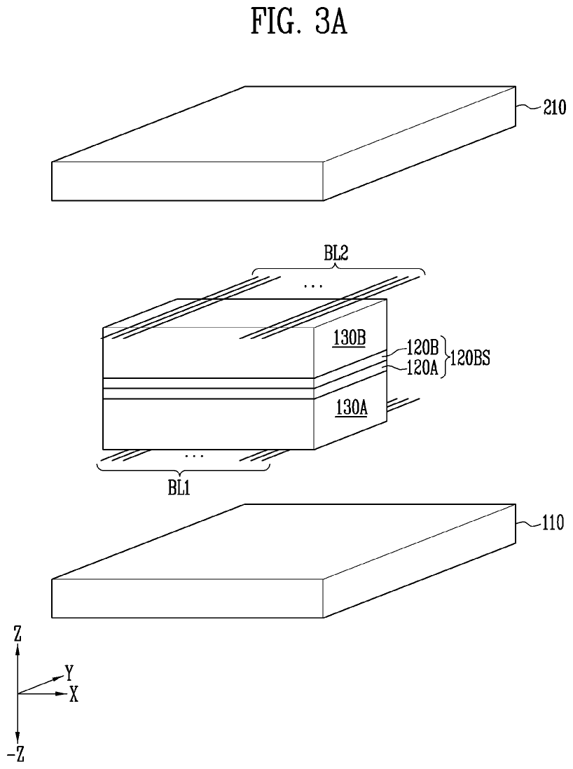

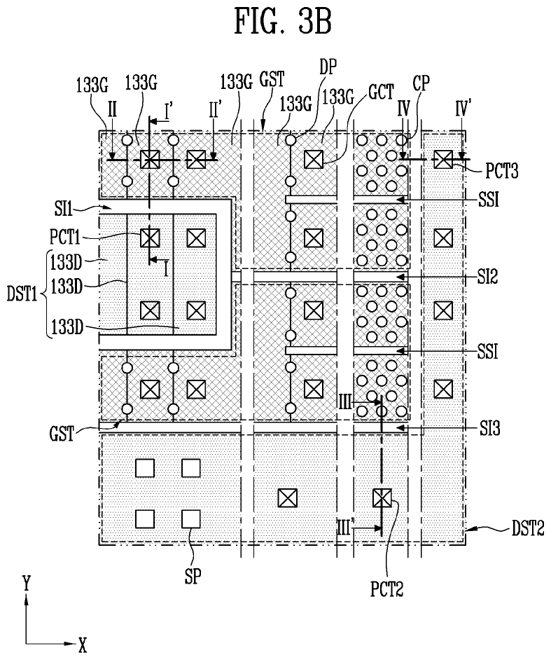

FIGS. 3A and 3B are diagrams illustrating a semiconductor memory device according to an embodiment of the present disclosure. FIG. 3A is a diagram illustrating a vertical arrangement of the semiconductor memory device, and FIG. 3B is a plan view illustrating a memory cell array structure and contact structures of the semiconductor memory device.

Referring to FIG. 3A, the semiconductor memory device may include a peripheral circuit structure 110, a plurality of first bit lines BL1, a first memory cell array structure 130A, a source bonding structure 120BS, a second memory cell array 130B, a plurality of second bit lines BL2, and an upper line array 210 may be included.

The source bonding structure 120BS may be connected to the common source line CSL shown in FIG. 1 or 2. The common source line CSL shown in FIG. 1 or 2 may be electrically connected to the first memory cell array structure 130A and the second memory cell array structure 130B via the source bonding structure 120BS.

The source bonding structure 120BS may include a first source layer 120A and a second source layer 120B bonded to each other. Each of the first source layer 120A and the second source layer 120B may be formed in a flat plate shape. As an embodiment, each of the first source layer 120A and the second source layer 120B may be a planar shape extending in an XY plane.

The first memory cell array structure 130A and the second memory cell array structure 130B may be included in the memory cell array 10 shown in FIG. 1. Each of the first memory cell array structure 130A and the second memory cell array structure 130B may include the memory block BLK described with reference to FIG. 2. The first memory cell array structure 130A and the second memory cell array structure 130B may be disposed with the source bonding structure 120BS interposed therebetween. Specifically, the source bonding structure 120BS may include a first surface facing a first direction (for example, a −Z-axis direction) and a second direction facing a second direction (for example, a Z-axis direction) opposite to the first direction. The first surface may be a surface of the first source layer 120A facing the first direction, and the second surface may be a surface of the second source layer 120B facing the second direction. The first memory cell array structure 130A may be adjacent to the first surface of the source bonding structure 120BS to overlap the first source layer 120A. The second memory cell array structure 130B may be adjacent to the second surface of the source bonding structure 120BS to overlap the second source layer 120B. The first memory cell array structure 130A may include a plurality of memory cell strings electrically connected to the first source layer 120A and the plurality of first bit lines BL1. The second memory cell array structure 130B may include a plurality of memory cell strings electrically connected to the second source layer 120B and the plurality of second bit lines BL2.

The plurality of first bit lines BL1 may overlap the source bonding structure 120BS with the first memory cell array structure 130A interposed therebetween. The plurality of second bit lines BL2 may overlap the source bonding structure 120BS with the second memory cell array structure 130B interposed therebetween.

The peripheral circuit structure 110 may be disposed to be adjacent to the plurality of first bit lines BL1. The upper line array 210 may be disposed to be adjacent to the plurality of second bit lines BL2. The peripheral circuit structure 110 may include a plurality of transistors, a capacitor, a resistor, and the like configuring the peripheral circuit 40 shown in FIG. 1. The upper line array 210 may include a plurality of upper conductive patterns.

Because, in an embodiment, the first memory cell array structure 130A and the second memory cell array structure 130B are disposed to overlap between the peripheral circuit structure 110 and the upper line array 210, an integration degree of the semiconductor memory device may be improved.

At least one of an interconnection group, a via group, and a bonding pad group may be disposed between the peripheral circuit structure 110 and the plurality of first bit lines BL1. At least one of the interconnection group, the via group, and the bonding pad group may be disposed between the plurality of second bit lines BL2 and the upper line array 210.

Referring to FIG. 3B, each of the first memory cell array structure 130A and the second memory cell array structure 130B shown in FIG. 3A may include a plurality of gate stacks GST and a plurality of cell plugs CP disposed in each gate stack of the plurality of gate stacks GST.

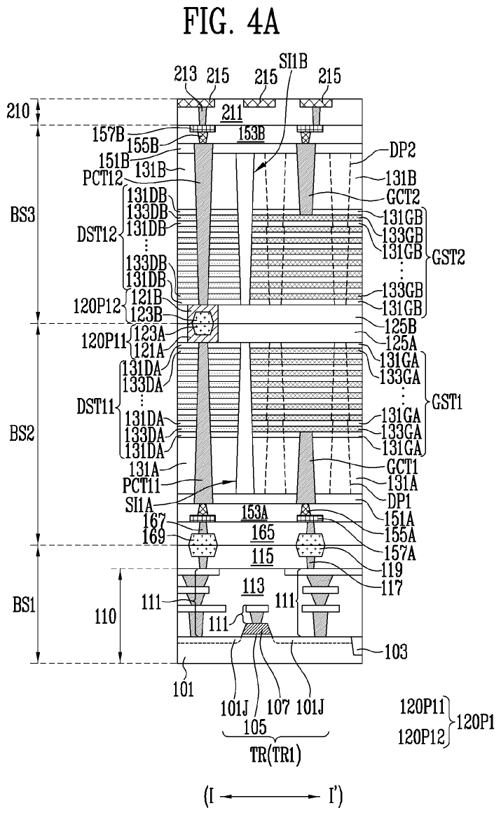

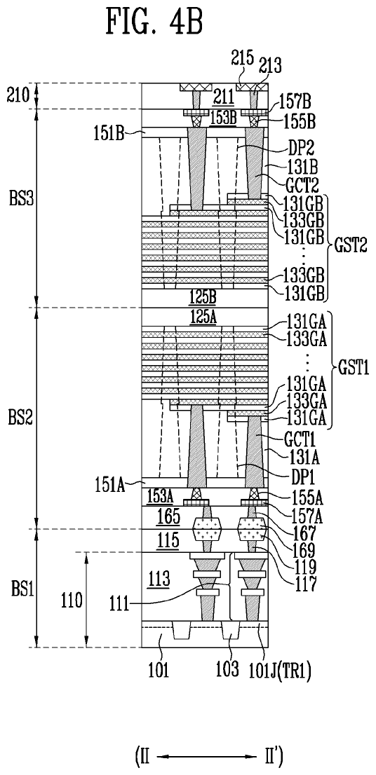

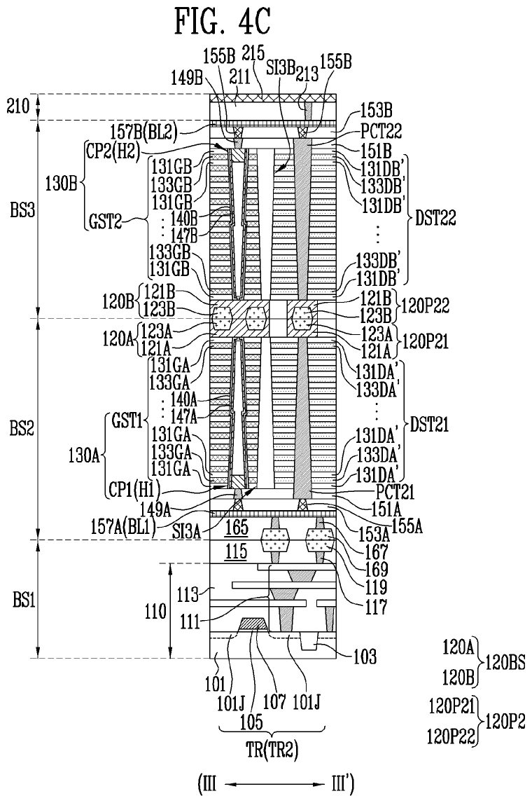

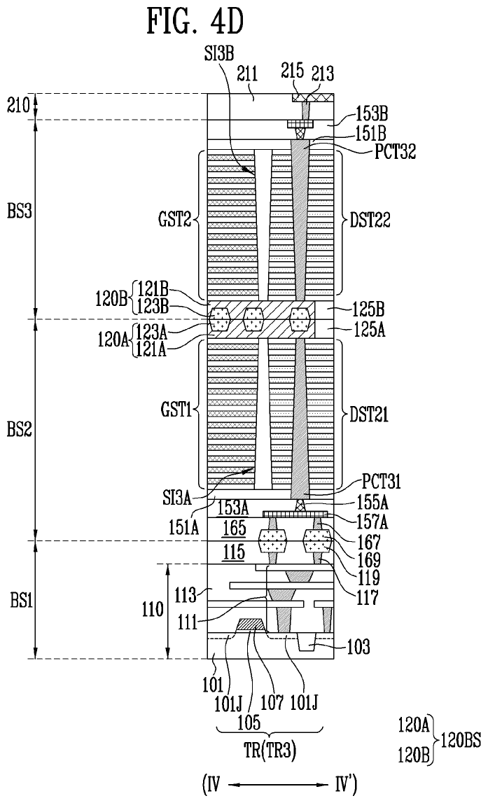

The gate stack GST may include a plurality of conductive patterns 133G stacked to be spaced apart in the first direction or the second direction described with reference to FIG. 3A. The plurality of conductive patterns 133G may form the source select line SSL, the drain select line DSL1 or DSL2, and the plurality of word lines WL1 to WLn shown in FIG. 2. The gate stack GST may be divided into a first gate stack GST1 and a second gate stack GST2 shown in FIGS. 4A to 4D.

The gate stack GST may include a contact area and a cell array area. The gate stack GST may be adjacent to a first group of dummy insulating stack DST1 and a second group of dummy insulating stack DST2. The first group of dummy insulating stack DST1 may be adjacent to the contact area of the gate stack GST. The second group of dummy insulating stack DST2 may be disposed to surround the plurality of gate stacks GST. The first group of dummy insulating stack DST1 may be divided into a first group of first dummy insulating stack DST11 and a first group of second dummy insulating stack DST12 shown in FIG. 4A. The second group of dummy insulating stack DST2 may be divided into a second group of first dummy insulating stack DST21 and a second group of second dummy insulating stack DST22 shown in FIGS. 4C and 4D.

The plurality of conductive patterns 133G may be respectively connected to a plurality of gate contact structures GCT in the contact area of the gate stack GST. The plurality of gate contact structures GCT may be divided into a first group of gate contact structure GCT1 and a second group of gate contact structure GCT2 shown in FIGS. 4A and 4B.

As an embodiment, the plurality of conductive patterns 133G may include a plurality of ends forming a stepped structure in the contact area of the gate stack GST. The plurality of gate contact structures GCT may be connected to the end of the plurality of conductive patterns 133G forming the stepped structure to transmit an electrical signal to the plurality of conductive patterns 133G. An embodiment of the present disclosure is not limited to forming the contact area of the gate stack GST in the stepped structure. Although not shown in the drawing, as another embodiment, the plurality of ends of the plurality of conductive patterns 133G may be aligned to overlap each other. At this time, each gate contact structure GCT may be formed to pass through the plurality of ends, to be in contact with the conductive pattern 133G corresponding thereto, and to be spaced apart from remaining conductive patterns 133G.

A dummy plug DP may be disposed around each gate contact structure GCT. The dummy plug DP may pass through the gate stack GST. The dummy plug DP may be divided into a first dummy plug DP1 and a second dummy plug DP2 shown in FIGS. 4A and 4B.

The plurality of conductive patterns 133G may be penetrated by the plurality of cell plugs CP in the cell array area of the gate stack GST. A memory cell string may be defined along each cell plug CP. The cell plug CP may be divided into a first cell plug CP1 and a second cell plug CP2 shown in FIG. 4C.

The gate stack GST may be partitioned by a slit. As an embodiment, the gate stack GST may be partitioned through a connection structure between a first slit SI1, a second slit SI2, and a third slit SI3. The first slit SI1 may extend to surround a sidewall of the first group of dummy insulating stack DST1. The first slit SI1 may be disposed between the first group of dummy insulating stack DST1 and the gate stack GST. The first slit SI1 may be divided into a first group of first slit SI1A and a second group of first slit SI1B shown in FIG. 4A. The second slit SI2 may extend from the first slit SI1 and may extend along the sidewall of the gate stack GST in the cell array area. The second slit SI2 may be disposed between the gate stacks GST adjacent to each other. The third slit SI3 may be disposed between the second dummy insulating stack DST2 and the gate stack GST. The third slit SI3 may be divided into a first group of third slit SI3A and a second group of third slit SI3B shown in FIGS. 4C and 4D. As an embodiment, each of the first slit SI1, the second slit SI2, and the third slit SI3 may be filled with an insulating material. As another embodiment, an insulating material and a conductive material may be disposed inside each of the first slit SI1, the second slit SI2, and the third slit SI3. An arrangement and a shape of the first to third slits SI1 to SI3 are not limited to those shown in the drawing and may be variously changed.

Some of the plurality of conductive patterns 133G of the gate stack GST may be partitioned by a select line separation slit SSI in addition to the first slit SI1, the second slit SI2, and the third slit SI3. The select line separation slit SSI may pass through a portion of the gate stack GST, and some of the plurality of conductive patterns 133G of the gate stack GST may extend along the XY plane to overlap the select line separation slit SSI. As an embodiment, the conductive patterns 133G serving as the first drain select line DSL1 and the second drain select line DSL2 shown in FIG. 2 may be separated from each other on the same plane by the select line separation slit SSI. The conductive patterns 133G serving as the plurality of word lines WL1 to WLn shown in FIG. 2 may expand along the XY plane to overlap the conductive patterns 133G serving as the first drain select line DSL1 and the second drain select line DSL2 and the select line separation slit SSI. At this time, a depth of the select line separation slit SSI may be controlled so as not to pass through the conductive patterns 133G serving as the plurality of word lines WL1 to WLn shown in FIG. 2.

Each of the first group of dummy insulating stack DST1 and the second group of dummy insulating stack DST2 may include a plurality of dummy sacrificial patterns 133D stacked to be spaced apart in the first direction and the second direction described with reference to FIG. 3A. The first group of dummy insulating stack DST1 may be penetrated by a first group of contact structure PCT1. The second group of dummy insulating stack DST2 may be penetrated by a second group of contact structure PCT2 and a third group of contact structure PCT3. The first group of contact structure PCT1 may be divided into a first group of first contact structure PCT11 and a first group of second contact structure PCT12 shown in FIG. 4A. The second group of contact structure PCT2 may be divided into a second group of first contact structure PCT21 and a second group of second contact structure PCT22 shown in FIG. 4C. The third group of contact structure PCT3 may be divided into a third group of first contact structure PCT31 and a third group of second contact structure PCT32 shown in FIG. 4D. Each of the first group of dummy insulating stack DST1 and the second group of dummy insulating stack DST2 may be penetrated by a support pillar SP. An arrangement and a shape of the first to third groups of contact structures PCT1 to PCT3, the support pillar SP, and the gate contact structure GCT are not limited to those shown in the drawing and may be variously changed.

FIGS. 4A, 4B, 4C, and 4D are cross-sectional views illustrating the semiconductor memory device shown in FIG. 3B. FIG. 4A is a cross-sectional view of the semiconductor memory device taken along a line I-I′ shown in FIG. 3B. FIG. 4B is a cross-sectional view of the semiconductor memory device taken along a line II-II′ shown in FIG. 3B. FIG. 4C is a cross-sectional view of the semiconductor memory device taken along a line III-III′ shown in FIG. 3B. FIG. 4D is a cross-sectional view of the semiconductor memory device taken along a line IV-IV′ shown in FIG. 3B.

Referring to FIGS. 4A to 4D, the semiconductor memory device may include a first bonding structure BS1, a second bonding structure BS2 connected to the first bonding structure BS1, a third bonding structure connected to the second bonding structure BS2, and an upper line array 210 adjacent to the third bonding structure BS3.

The first bonding structure BS1 may include a peripheral circuit structure 110, a first via group 117 connected to the peripheral circuit structure 110, and a first bonding pad group 119 connected to the first via group 117. The peripheral circuit structure 110 may include a plurality of transistors TR and a first interconnection group 111 connected to the plurality of transistors TR. The first via group 117 may be connected to the plurality of transistors TR via the first interconnection group 111.

Each transistor TR may include a gate insulating layer 105 overlapping an active area of a semiconductor substrate 101, a gate electrode 107 overlapping the gate insulating layer 105, and junctions 101J formed in the active area on both sides of the gate electrode 107. The active area of the semiconductor substrate 101 may be partitioned by an isolation layer 103. Transistors TR adjacent to each other may be insulated from each other by the isolation layer 103. The junction 101J may be provided as a source area and a drain area of the transistor TR, and may include at least one of an n-type impurity and a p-type impurity.

The plurality of transistors TR may include a first transistor TR1, a second transistor TR2, and a third transistor TR3. The first transistor TR1 may be included in the row decoder 33 shown in FIG. 1. The second transistor TR2 may be included in the page buffer 37 shown in FIG. 1. The third transistor TR3 may be included in the source line driver 39 shown in FIG. 1. The first interconnection group 111 may include a plurality of routing lines and a plurality of conductive contact structures. The plurality of transistors TR and the first interconnection group 111 may be disposed inside a first insulating structure 113. The first insulating structure 113 may include a two or more layers of multilayer insulating layer stacked on the semiconductor substrate 101.

The first via group 117 may include a plurality of conductive plugs. The first bonding pad group 119 may include a plurality of conductive bonding pads. The first via group 117 and the first bonding pad group 119 may be disposed inside a second insulating structure 115. The second insulating structure 115 may include a single layer of insulating layer or two or more layers of multilayer insulating layer. The first bonding pad group 119 may be electrically connected to the peripheral circuit structure 110 via the first via group 117.

The second bonding structure BS2 may include a second bonding pad group 169, a second via group 167, a first line array 157A, a third via group 155A, a first memory cell array structure 130A, a first group of dummy insulating stack DST11, a second group of first dummy insulating stack DST21, a first group of gate contact structure GCT1, a first group of first contact structure PCT11, a second group of first contact structure PCT21, a third group of first contact structure PCT31, a first source layer 120A, and a plurality of first pad patterns 120P11 and 120P21.

The second bonding pad group 169 may include a plurality of conductive bonding pads. The second bonding pad group 169 may be bonded to the first bonding pad group 119. The second via group 167 may include a plurality of conductive plugs. The second via group 167 may be electrically connected to the first bonding pad group 119 via the second bonding pad group 169. The second bonding pad group 169 and the second via group 167 may be disposed inside the third insulating structure 165. The third insulating structure 165 may include a single layer of insulating layer or two or more layers of multilayer insulating layer.

The first line array 157A and the third via group 155A may be disposed inside a fourth insulating structure 153A. The fourth insulating structure 153A may overlap the third insulating structure 165. The fourth insulating structure 153A may include a single layer of insulating layer or two or more layers of multilayer insulating layer. The first line array 157A may be connected to the second via group 167 and may include a plurality of conductive lines. Some of the plurality of conductive lines may be a first bit line BL1 connected to a first cell plug CP1 of the first memory cell array structure 130A. The first line array 157A may be connected to the first bonding pad group 119 via the second via group 167 and the second bonding pad group 169.

The first memory cell array structure 130A may include the first gate stack GST1 and the first cell plug CP1. The first gate stack GST1 may be disposed between the first bit line BL1 and the first source layer 120A. The first gate stack GST1 may include a plurality of first conductive patterns 133GA stacked to be spaced apart in the first direction. The first gate stack GST1 may include a plurality of first interlayer insulating layers 131GA disposed alternately with the plurality of first conductive patterns 133GA in the first direction. The first cell plug CP1 may be disposed inside a first hole H1 passing through the first gate stack GST1. The first cell plug CP1 may include a first channel layer 147A disposed inside the first hole H1 and a first memory layer 140A between the first channel layer 147A and the first gate stack GST1. The plurality of first conductive patterns 133GA may serve as a source select line, a plurality of word lines, and a drain select line of the first memory cell array structure 130A. The first gate stack GST1 may be penetrated by the first dummy plug DP1.

The first channel layer 147A may be connected to the first source layer 120A and the first bit line BL1. As an embodiment, the first channel layer 147A may be connected to the first bit line BL1 via a first bit line contact 149A. The first bit line contact 149A may pass through a first intervening insulating layer 151A between the fourth insulating structure 153A and the first gate stack GST1. The first channel layer 147A may contact the first source layer 120A to be electrically connected to the first source layer 120A.

The first group of gate contact structure GCT1 may include a plurality of first gate contact structures individually connected to the plurality of first conductive patterns 133GA. When the first gate stack GST1 includes a stepped structure formed of the ends of the plurality of first conductive patterns 133GA, a first gap-fill insulating layer 131A may be disposed between the stepped structure and the first intervening insulating layer 151A. The first gap-fill insulating layer 131A and the first intervening insulating layer 151A may be penetrated by the first group of gate contact structure GCT1.

The first source layer 120A may be disposed inside a first source level insulating layer 125A. The first source level insulating layer 125A may be interposed between the first gate stack GST1 and the third bonding structure BS3. The first source level insulating layer 125A may be penetrated by the plurality of first pad patterns 120P11 and 120P21. The plurality of first pad patterns 120P11 and 120P21 may include a first group of first pad pattern 120P11 and a second group of first pad pattern 120P21. The first group of first pad pattern 120P11 may overlap the first group of first dummy insulating stack DST11, and the second group of first pad pattern 120P21 may overlap the second group of first dummy insulating stack DST21.

The first group of first dummy insulating stack DST11 may be disposed between the first group of first pad pattern 120P11 and the peripheral circuit structure 110. The second group of first dummy insulating stack DST21 may be disposed between the second group of first pad pattern 120P21 and the peripheral circuit structure 110. The second group of first dummy insulating stack DST21 may extend between the first source layer 120A and the peripheral circuit structure 110.

Each of the first group of first dummy insulating stack DST11 and the second group of first dummy insulating stack DST21 may include a plurality of first dummy sacrificial patterns 133DA or 133DA stacked to be spaced apart in the first direction. Each of the first group of first dummy insulating stack DST11 and the second group of first dummy insulating stack DST21 may further include a plurality of first dummy interlayer insulating layers 131DA or 131DA′ disposed alternately with the plurality of first dummy sacrificial patterns 133DA or 133DA′ in the first direction. The plurality of first dummy sacrificial patterns 133DA or 133DA′ may include an insulating material having an etch selectivity with respect to the plurality of first dummy interlayer insulating layers 131DA or 131DA′. As an embodiment, the plurality of first dummy sacrificial patterns 133DA or 133DA′ may include a nitride such as a silicon nitride layer. The plurality of first dummy interlayer insulating layers 131DA or 131DA′ may include the same insulating material as the plurality of first dummy interlayer insulating layers 131GA. As an embodiment, the plurality of first dummy interlayer insulating layers 131DA or 131DA′ and the plurality of first interlayer insulating layers 131GA may include an oxide such as a silicon oxide layer.

Each of the first group of first dummy insulating stack DST11 and the second group of first dummy insulating stack DST21 may be disposed at substantially the same level as the first gate stack GST1. As an embodiment, the plurality of first dummy interlayer insulating layers 131DA or 131DA′ may be disposed at substantially the same level as the plurality of first dummy interlayer insulating layers 131GA, and the plurality of first dummy sacrificial patterns 133DA or 133DA′ may be disposed at substantially the same level as the plurality of first conductive patterns 133GA.

The first group of first contact structure PCT11 may be connected to the first group of first pad pattern 120P11 and may extend to pass through the first group of first dummy insulating stack DST11. The second group of first contact structure PCT21 may be connected to the second group of first pad pattern 120P21 and may extend to pass through the second group of first dummy insulating stack DST21. The third group of first contact structure PCT31 may be connected to the first source layer 120A and may extend to pass through the second group of first dummy insulating stack DST21.

The first group of first contact structure PCT11, the second group of first contact structure PCT21, and the third group of first contact structure PCT31 may be electrically connected to the second bonding pad group 169 via the third via group 155A, the first line array 157A, and the second via group 167. As an embodiment, the first group of first contact structure PCT11 may be connected to the first transistor TR1 via the third via group 155A, the first line array 157A, the second via group 167, the second bonding pad group 169, the first bonding pad group 119, and the first interconnection group 111. The second group of first contact structure PCT21 may be connected to the second transistor TR2 via the third via group 155A, the first bit line BL1 of the first line array 157A, the second via group 167, the second bonding pad group 169, the first bonding pad group 119, and the first interconnection group 111. The third group of first contact structure PCT31 may be connected to the third transistor TR3 via the third via group 155A, the first line array 157A, the second via group 167, the second bonding pad group 169, the first bonding pad group 119, and the first interconnection group 111.

The third bonding structure BS3 may include the second source layer 120B, a plurality of second pad patterns 120P12 and 120P22, a second memory cell array structure 130B, the first group of second dummy insulating stack DST12, the second group of second dummy insulating stack DST22, the second group of gate contact structure GCT2, the first group of second contact structure PCT12, the second group of second contact structure PCT22, the third group of second contact structure PCT32, a fourth via group 155B, and a second line array 157B.

The second source layer 120B may be bonded to the first source layer 120A to form the source bonding structure 120BS. The second source layer 120B may be disposed inside a second source level insulating layer 125B overlapping the first source level insulating layer 125A. The second source level insulating layer 125B may be penetrated by the plurality of second pad patterns 120P12 and 120P22. The plurality of second pad patterns 120P12 and 120P22 may include a first group of second pad pattern 120P12 and a second group of second pad pattern 120P22. The first group of second pad pattern 120P12 may be bonded to the first pad pattern 120P11 to form the first pad bonding structure 120P1. The second group of second pad pattern 120P22 may be bonded to the second group of first pad pattern 120P21 to form the second pad bonding structure 120P2. The first pad bonding structure 120P1 and the second pad bonding structure 120P2 may be disposed at a level where the source bonding structure 120BS is disposed.

The second line array 157B and the fourth via group 155B may be disposed inside a fifth insulating structure 153B. The fifth insulating structure 153B may overlap the second memory cell array structure 130B. The second line array 157B may include a plurality of conductive lines. Some of the plurality of conductive lines may be the second bit line BL2 connected to the second cell plug CP2 of the second memory cell array structure 130B.

The second memory cell array structure 130B may include the second gate stack GST2 and the second cell plug CP2. The second gate stack GST2 may be disposed between the second bit line BL2 and the second source layer 120B. The second gate stack GST2 may include a plurality of second conductive patterns 133 GB stacked to be spaced apart in the second direction opposite to the first direction. The second gate stack GST2 may include a plurality of second interlayer insulating layers 131 GB disposed alternately with the plurality of second conductive patterns 133 GB in the second direction. The second cell plug CP2 may be disposed inside a second hole H2 passing through the second gate stack GST2. The second cell plug CP2 may include a second channel layer 147B disposed inside the second hole H2 and a second memory layer 140B between the second channel layer 147B and the second gate stack GST2. The second gate stack GST2 may be penetrated by the second dummy plug DP2.

The plurality of second conductive patterns 133 GB may serve as a source select line, a plurality of word lines, and a drain select line of the second memory cell array structure 130B.

The second channel layer 147B may be connected to the second source layer 120B and the second bit line BL2. The second channel layer 147B may be connected to the second bit line BL2 via the second bit line contact 149B. The second bit line contact 149B may pass through the fifth insulating structure 153B and a second intervening insulating layer 151B. The second intervening insulating layer 151B may be disposed between the fifth insulating structure 153B and the second gate stack GST2. In addition, the second channel layer 147B may contact the second source layer 120B to be electrically connected to the second source layer 120B.

The second group of gate contact structure GCT2 may include a plurality of second gate contact structures individually connected to the plurality of second conductive patterns 133 GB. The second group of gate contact structure GCT2 may pass through a second gap fill insulating layer 131B and the second intervening insulating layer 151B. The second gap-fill insulating layer 131B and the second intervening insulating layer 151B may be disposed between the second gate stack GST2 and the fifth insulating structure 153B.

The first group of second dummy insulating stack DST12 may overlap the first group of first dummy insulating stack DST11 with the first pad bonding structure 120P1 interposed therebetween. The second group of second dummy insulating stack DST22 may overlap the second group of first dummy insulating stack DST21 with the second pad bonding structure 120P2 interposed therebetween.

Each of the first group of second dummy insulating stack DST12 and the second group of second dummy insulating stack DST22 may include a plurality of second dummy sacrificial patterns 133DB or 133DB′ stacked to be spaced apart in the second direction. Each of the first group of second dummy insulating stack DST12 and the second group of second dummy insulating stack DST22 may further include a plurality of second dummy interlayer insulating layers 131DB or 131DB′ disposed alternately with the plurality of second dummy sacrificial patterns 133DB or 133DB′ in the second direction.

Each of the first group of second dummy insulating stack DST12 and the second group of second dummy insulating stack DST22 may be disposed at substantially the same level as the second gate stack GST2. As an embodiment, the plurality of second dummy interlayer insulating layers 131DB or 131DB′ may be disposed at substantially the same level as the plurality of second interlayer insulating layers 131 GB, and the plurality of second dummy sacrificial patterns 133DB or 133DB′ may be disposed at substantially the same level as the plurality of second conductive patterns 133 GB.

The first group of second dummy insulating stack DST12 may be penetrated by the first group of second contact structure PCT12. The second group of second dummy insulating stack DST22 may be penetrated by the second group of second contact structure PCT22 and the third group of second contact structure PCT32.

The second line array 157B may be electrically connected to the first group of second contact structure PCT12, the second group of second contact structure PCT22, and the third group of second contact structure PCT32 via the fourth via group 155B. The first group of second contact structure PCT12 may be electrically connected to the first group of second pad pattern 120P12. The first group of second contact structure PCT12 may be connected to the first transistor TR1 via the first pad bonding structure 120P1 and the first group of first contact structure PCT11. The second group of second contact structure PCT22 may be electrically connected to the second group of second pad pattern 120P22 and the second bit line BL2 of the second line array 157B. The second group of second contact structure PCT22 may be connected to the second transistor TR2 via the second pad bonding structure 120P2 and the second group of first contact structure PCT21. The third group of second contact structure PCT32 may be electrically connected to the second source layer 120B. The third group of second contact structure PCT32 may be connected to the third transistor TR3 via the source bonding structure 120BS and the third group of first contact structure PCT31.

According to the above-described structure, an operation of the first bit line BL1 and the second bit line BL2 may be controlled through the same second transistor TR2. In addition, an operation of the first source layer 120A and the second source layer 120B may be controlled through the same third transistor TR3.

The upper line array 210 may include a plurality of upper conductive plugs 213 and a plurality of upper routing lines 215 disposed in the upper insulating layer 211. The upper line array 210 may be designed in various structures to transmit an electrical signal from the peripheral circuit structure 110 or an electrical signal from an external device.

Each of the first group of first pad pattern 120P11 and the second group of first pad pattern 120P21 may include the same material as the first source layer 120A. Each of the first group of second pad pattern 120P12 and the second group of second pad pattern 120P22 may include the same material as the second source layer 120B.

As an embodiment, each of the first source layer 120A, the first group of first pad pattern 120P11, and the second group of first pad pattern 120P21 may include a first doped semiconductor layer 121A and a metal layer 123A. Although not shown in the drawing, a first barrier layer such as titanium nitride may be interposed between the first doped semiconductor layer 121A and the first metal layer 123A.

Each of the second source layer 120B, the first group of second pad pattern 120P12, and the second group of second pad pattern 120P22 may include a second doped semiconductor layer 121B and a second metal layer 123B. Although not shown in the drawing, a second barrier layer such as titanium nitride may be interposed between the second doped semiconductor layer 121B and the second metal layer 123B.

Each of the first doped semiconductor layer 121A and the second doped semiconductor layer 121B may include at least one of an n-type impurity and a p-type impurity. As an embodiment, each of the first doped semiconductor layer 121A and the second doped semiconductor layer 121B may include doped silicon including at least one of an n-type impurity and a p-type impurity.

Each of the first and metal layers 123A and 123B may include a metal having resistivity less than that of each of the first and doped semiconductor layers 121A and 121B to, in an embodiment, reduce a resistance of the first source layer 120A, the first group of first pad pattern 120P11, the second group of first pad pattern 120P21, the second source layer 120B, the first group of second pad pattern 120P21, and the second group of second pad pattern 120P22. As an embodiment, the first metal layer 123A and the second metal layer 123B may include copper.

The first metal layer 123A and the second metal layer 123B may be disposed in the first doped semiconductor layer 121A and the second doped semiconductor layer 121B by a damascene process. Accordingly, each of the source bonding structure 120BS, the first pad bonding structure 120P1, and the second pad bonding structure 120P2 may be provided as a hybrid bonding structure.

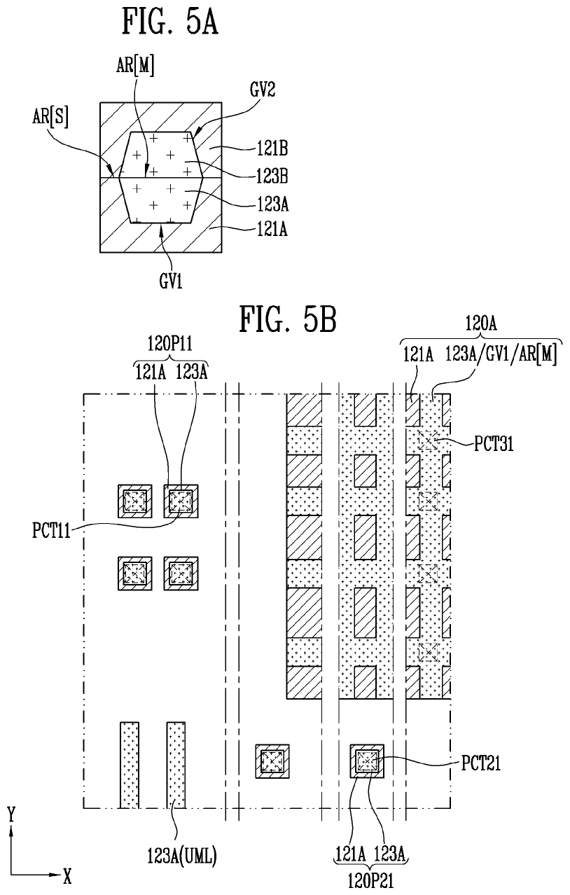

FIGS. 5A and 5B are diagrams illustrating a partial configuration of the semiconductor memory device described with reference to FIGS. 3A, 3B, and 4A to 4D.

FIG. 5A is a cross-sectional view illustrating the hybrid bonding structure.

Referring to FIG. 5A, each of the source bonding structure 120BS, the first pad bonding structure 120P1, and the second pad bonding structure 120P2 shown in FIGS. 4A to 4D may be provided as the hybrid bonding structure including a semiconductor bonding area AR[S] and a metal bonding area AR[M].

The semiconductor bonding area AR[S] may be defined by bonding between the first doped semiconductor layer 121A and the second doped semiconductor layer 121B, and the metal bonding area AR[M] may be defined by bonding between the first metal layer 123A and the second metal layer 123B. The first metal layer 123A may be buried in a first groove GV1 inside the first doped semiconductor layer 121A. The second metal layer 123B may be buried in a second groove GV2 inside the second doped semiconductor layer 121B.

Because the first metal layer 123A and the second metal layer 123B are buried inside the first groove GV1 of the first doped semiconductor layer 121A and the second groove GV2 of the second doped semiconductor layer 121B, a thickness increase due to addition of a metal layer for a low-resistance line may be prevented or mitigated. Accordingly, in an embodiment, a structure advantageous to miniaturization of the semiconductor memory device may be provided.

FIG. 5B is a plan view illustrating a level where a metal layer of a hybrid bonding structure is disposed. FIG. 5B is a plan view of a level where the first metal layer 123A is disposed. Although not shown in the drawing, the second metal layer 123B shown in FIG. 5A may be formed in a layout similar to that of the first metal layer 123A.

Referring to FIG. 5B, the first metal layer 123A may overlap a contact structure PCT11, PCT21, or PCT31 corresponding thereto. The first metal layer 123A may be divided into a pattern buried in the first groove GV1 of the first doped semiconductor layer 121A of each of the first source layer 120A, the first group of first pad pattern 120P11, and the second group of first pad pattern 120P21, and a pattern provided as a lower routing line UML.

The first groove GV1 of the first source layer 120A and the first metal layer 123A may be provided in a mesh shape structure. Accordingly, the metal bonding area AR[M] may be provided in a mesh shape structure. In an embodiment, each of the first metal layer 123A and the second metal layer 123B shown in FIGS. 5A and 5B may include a plurality of first line portions and a plurality of second line portions. The plurality of first line portions may parallel to each other and the plurality of second line portions may parallel to each other. In each of the first metal layer 123A and the second metal layer 123B shown in FIGS. 5A and 5B, the plurality of second line portions may intersect with the plurality of first line portions to form the mesh shaped structure. Although not shown in the drawing, a metal bonding area for a source bonding structure may be provided in a flat planar shape equal to that of the first source layer 120A. An intermetallic bonding defect may be reduced in the metal bonding area AR[M] of the mesh shape structure as in an embodiment of the present disclosure rather than in the metal bonding area of the flat planar shape having a large area.

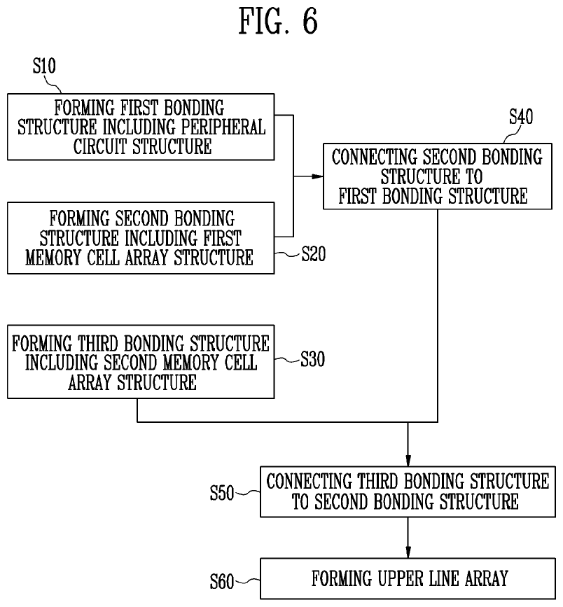

FIG. 6 is a flowchart illustrating a method of manufacturing a semiconductor memory device according to an embodiment of the present disclosure.

Referring to FIGS. 3A, 4A to 4D, and 6, in step S10, the first bonding structure BS1 including the peripheral circuit structure 110 may be formed. In step S20, the second bonding structure BS2 including the first memory cell array structure 130A may be formed. At this time, the second bonding structure BS2 may be formed on a first wafer (not shown). In step S30, the third bonding structure BS3 including the second memory cell array structure 130B may be formed. At this time, the third bonding structure BS3 may be formed on a second wafer (not shown).

In step S40, a bonding process for connecting the second bonding structure BS2 to the first bonding structure BS1 may be performed. At this time, the second bonding pad group 169 of the second bonding structure BS2 may be bonded to the first bonding pad group 119 of the first bonding structure BS1. Thereafter, the first wafer may be removed to expose the first source layer 120A of the second bonding structure BS2, the first group of first pad pattern 120P11, and the second group of first pad pattern 120P21. As another embodiment, the first source layer 120A of the second bonding structure BS2, the first group of first pad pattern 120P11, and the second group of first pad pattern 120P21 may be formed after removing the first wafer.

In step S50, a bonding process for connecting the third bonding structure BS3 to the second bonding structure BS2 may be performed. At this time, the second source layer 120B of the third bonding structure BS3, the first group of second pad pattern 120P12, and the second group of second pad pattern 120P22 may be bonded to the first source layer 120A of the second bonding structure BS2, the first group of first pad pattern 120P11, and the second group of first pad pattern 120P21. Thereafter, the second wafer may be removed. As another embodiment, the second line array 157B of the third bonding structure BS3 may be formed after removing the second wafer.

In step S60, the upper line array 210 may be formed on the third bonding structure BS3.

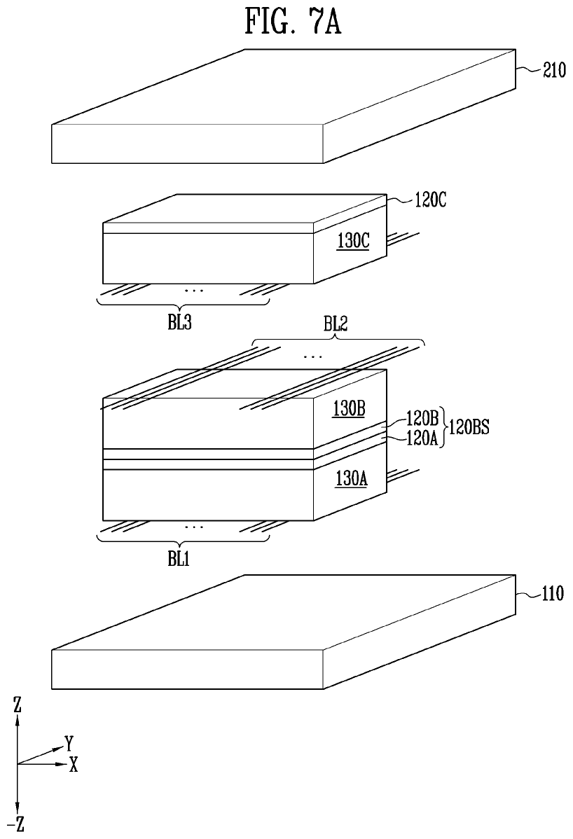

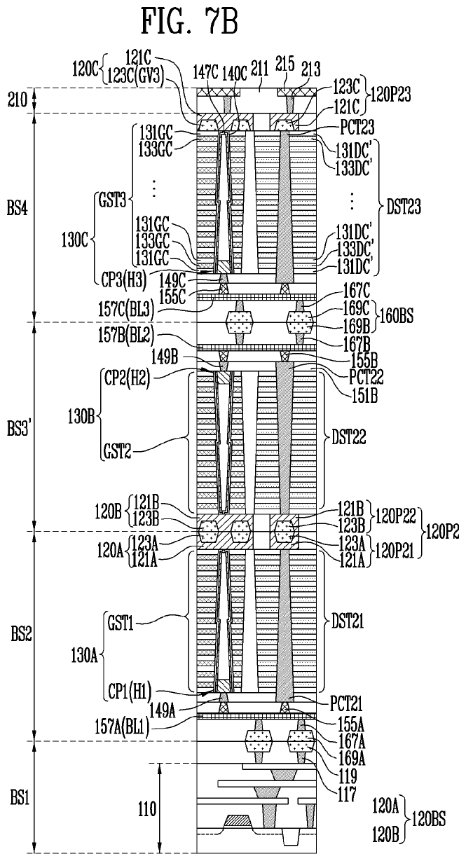

FIGS. 7A and 7B are diagrams illustrating a semiconductor memory device according to an embodiment of the present disclosure. FIG. 7A is a diagram illustrating a vertical arrangement of the semiconductor memory device, and FIG. 7B is a cross-sectional view of the semiconductor memory device shown in FIG. 7A. Hereinafter, a detailed description of configurations overlapping those described with reference to FIGS. 3A and 4A to 4D is omitted.

Referring to FIG. 7A, the semiconductor memory device may include the peripheral circuit structure 110, the plurality of first bit lines BL1, the first memory cell array structure 130A, the source bonding structure 120BS including the first source layer 120A and the second source layer 120B, the second memory cell array structure 130B, the plurality of second bit lines BL2, a plurality of third bit lines BL3, a third memory cell array structure 130C, a third source layer 120C, and the upper line array 210.

The source bonding structure 120BS and the third source layer 120C may be connected to the common source line CSL shown in FIG. 1 or 2. The common source line CSL shown in FIG. 1 or 2 may be electrically connected to the first memory cell array structure 130A and the second memory cell array structure 130B via the source bonding structure 120BS, and may be electrically connected to the third memory cell array structure 130C via the third source layer 120C.

The plurality of third bit lines BL3 may overlap the plurality of second bit lines BL2. The third source layer 120C may overlap the second memory cell array structure 130B with the plurality of second bit lines BL2 and the plurality of third bit lines BL3 interposed therebetween. The third memory cell array structure 130C may be disposed between the plurality of third bit lines BL3 and the third source layer 120C.

The first memory cell array structure 130A, the second memory cell array structure 130B, and the third memory cell array structure 130C may be included in the memory cell array 10 shown in FIG. 1. Each of the first memory cell array structure 130A, the second memory cell array structure 130B, and the third memory cell array structure 130C may include the memory block BLK described with reference to FIG. 2.

The third memory cell array structure 130C may include a plurality of memory cell strings electrically connected to the plurality of third bit lines BL3 and the third source layer 120C. The upper line array 210 may be disposed to be adjacent to the plurality of third bit lines BL3.

Each of the first memory cell array structure 130A, the second memory cell array structure 130B, and the third memory cell array structure 130C may include the plurality of gate stacks GST shown in FIG. 3B and a plurality of cell plugs CP disposed inside the each of the gate stacks GST. More specifically, the first memory cell array structure 130A may include a first gate stack GST1 and a first cell plug CP1 as shown in FIG. 7B, the second memory cell array structure 130B may include a second gate stack GST2 and a second cell plug CP2 as shown in FIG. 7B, and the third memory cell array structure 130C may include a third gate stack GST3 and a third cell plug CP3 as shown in FIG. 7B.

Because, in an embodiment, the first memory cell array structure 130A, the second memory cell array structure 130B, and the third memory cell array structure 130C are disposed to overlap between the peripheral circuit structure 110 and the upper line array 210, the integration degree of the semiconductor memory device may be improved.

Referring to FIG. 7B, the semiconductor memory device may include the first bonding structure BS1, the second bonding structure BS2 connected to the first bonding structure BS1, a third bonding structure BS3′ connected to the second bonding structure BS2, a fourth bonding structure BS4 connected to the third bonding structure BS3′, and the upper line array 210 adjacent to the fourth bonding structure BS4.

As described with reference to FIGS. 4A to 4D, the first bonding structure BS1 may include the peripheral circuit structure 110, the first via group 117, and the first bonding pad group 119.

As described with reference to FIGS. 4A to 4D, the second bonding structure BS2 may include the second bonding pad group 169A, the second via group 167A, the first line array 157A including the first bit line BL1, the third via group 155A, the first memory cell array structure 130A, the first bit line contact 149A, the first dummy insulating stack DST21, the first contact structure PCT21, the first source layer 120A, and the first pad pattern 120P21. As described with reference to FIGS. 4A to 4D, the first cell plug CP1 of the first memory cell array structure 130A may include the first channel layer and the first memory layer disposed inside the first hole H1 passing through the first gate stack GST1. As described with reference to FIG. 5A, each of the first source layer 120A and the first pad pattern 120P21 may include the first doped semiconductor layer 121A having the first groove and the first metal layer 123A buried in the first groove.

As described with reference to FIGS. 4A to 4D, the third bonding structure BS3′ may include the second source layer 120B, the second pad pattern 120P22, the second memory cell array structure 130B, the second dummy insulating stack DST22, the second contact structure PCT22, the second bit line contact 149B, the fourth via group 155B, and the second line array 157B including the second bit line BL2. The third bonding structure BS3′ may further include a fifth via group 167B connected to the second line array 157B and a third bonding pad group 169B connected to the fifth via group 167B.

As described with reference to FIG. 5A, each of the second source layer 120B and the second pad pattern 120P22 may include the second doped semiconductor layer 121B having the second groove and the second metal layer 123B buried in the second groove. As described with reference to FIGS. 4A to 4D, the second source layer 120B may be bonded to the first source layer 120A to form the source bonding structure 120BS, and the second pad pattern 120P22 may be bonded to the first pad pattern 120P21 to form the pad bonding structure 120P2.

As described with reference to FIGS. 4A to 4D, the second cell plug CP2 of the second memory cell array structure 130B may include the second channel layer and the second memory layer disposed inside the second hole H2 passing through the second gate stack GST2.

The fourth via group 155B may contact a first surface of the second line array 157B facing the first direction (for example, the −Z-axis direction of FIG. 7A). The fifth via group 167B may contact a second surface of the second line array 157B facing the second direction (for example, the Z-axis direction of FIG. 7A) opposite to the first direction. The third bonding pad group 169B may be electrically connected to the second line array 157B via the fifth via group 167B.

The fourth bonding structure BS4 may include a fourth bonding pad group 169C, a sixth via group 167C, a third line array 157C including a third bit line BL3, a seventh via group 155C, a third bit line contact 149C, a third memory cell array structure 130C, a third dummy insulating stack DST23, a third contact structure PCT23, a third source layer 120C, and a third pad pattern 120P23. The fourth bonding structure BS4 may be similar to the second bonding structure BS2.

The fourth bonding pad group 169C may be bonded to the third bonding pad group 169B. A conductive bonding pad of the third bonding pad group 169B connected to the second bit line BL2 and a conductive bonding pad of the fourth bonding pad group 169C connected to the third bit line BL3 may form a bit line bonding structure 160BS. In other words, the second bit line BL2 and the third bit line BL3 may be connected to each other by the bit line bonding structure 160BS therebetween. The third line array 157C may be electrically connected to the fourth bonding pad group 169C via the sixth via group 167C.

The third memory cell array structure 130C may include a third gate stack GST3 and a third cell plug CP3. The third gate stack GST3 may include a plurality of conductive patterns 133GC and a plurality of interlayer insulating layers 131GC alternately stacked between the third bit line BL3 and the third source layer 120C. The third cell plug CP3 may be disposed inside a third hole H3 passing through the third gate stack GST3. The third cell plug CP3 may include a third channel layer 147C disposed inside the third hole H3 and a third memory layer 140C between the third channel layer 147C and the third gate stack GST3. The plurality of conductive patterns 133GC may serve as a source select line, a plurality of word lines, and a drain select line of the third memory cell array structure 130C.

The third dummy insulating stack DST23 may overlap the second dummy insulating stack DST22 with the third line array 157C and the bit line bonding structure 160BS interposed therebetween. The third dummy insulating stack DST23 may include a plurality of dummy sacrificial patterns 133DC′ and a plurality of dummy interlayer insulating layers 131DC′ alternately stacked with the plurality of dummy sacrificial patterns 133DC′. The plurality of dummy sacrificial patterns 133DC′ may include an insulating material having an etch selectivity with respect to the plurality of dummy interlayer insulating layers 131DC′. As an embodiment, the plurality of dummy sacrificial patterns 133DC′ may include a nitride such as a silicon nitride layer. The plurality of dummy interlayer insulating layers 131DC′ may include the same insulating material as the plurality of interlayer insulating layers 131GC. As an embodiment, the plurality of dummy interlayer insulating layers 131DC′ and the plurality of interlayer insulating layers 131GC may include an oxide such as a silicon oxide layer.

The third dummy insulating stack DST23 may be disposed on substantially the same level as the third gate stack GST3. As an embodiment, the plurality of dummy interlayer insulating layers 131DC′ may be disposed at substantially the same level as the plurality of interlayer insulating layers 131GC, and the plurality of dummy sacrificial patterns 133DC′ may be disposed at substantially the same level as the plurality of conductive patterns 133GC.

The third contact structure PCT23 may pass through the third dummy insulating stack DST23. As an embodiment, the third contact structure PCT23 may be disposed between the third pad pattern 120P23 and the third line array 157C.

The seventh via group 155C may include a plurality of conductive plugs disposed between the third line array 157C and the third gate stack GST3 and between the third line array 157C and the third dummy insulating stack DST23. A portion of the plurality of conductive plugs may be connected to the third channel layer 147C of the third memory cell array structure 130C via the third bit line contact 149C. Another portion of the plurality of conductive plugs may be connected to the third contact structure PCT23.

The third channel layer 147C may contact the third source layer 120C to be electrically connected to the third source layer 120C. The third pad pattern 123P23 may overlap the third dummy insulating stack DST23 at a level where the third source layer 120C is disposed. The third pad pattern 123P23 may be connected to the third contact structure PCT23.

The third pad pattern 123P23 may include the same material as the third source layer 120C. As an embodiment, each of the third pad pattern 123P23 and the third source layer 120C may include a third doped semiconductor layer 121C and a third metal layer 123C. Although not shown in the drawing, a barrier layer such as titanium nitride may be interposed between the third doped semiconductor layer 121C and the third metal layer 123C. The third doped semiconductor layer 121C may include at least one of an n-type impurity and a p-type impurity. As an embodiment, the third doped semiconductor layer 121C may include doped silicon including at least one of an n-type impurity and a p-type impurity. The third metal layer 123C may include a metal having resistivity less than that of the third doped semiconductor layer 121C. As an embodiment, the third metal layer 123C may include copper. The third metal layer 123C may be disposed in the third doped semiconductor layer 121C by a damascene process.

As described with reference to FIGS. 4A to 4D, the upper line array 210 may include the plurality of upper conductive plugs 213 and the plurality of upper routing lines 215.

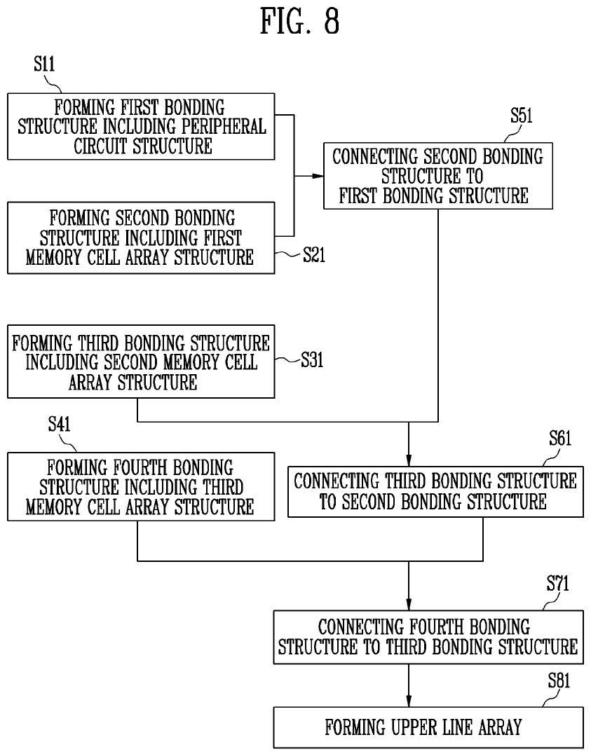

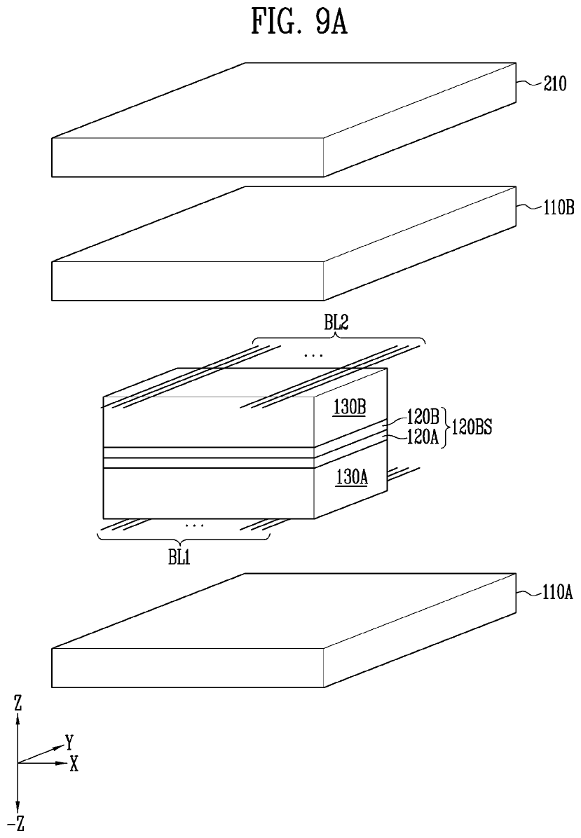

FIG. 8 is a flowchart illustrating a method of manufacturing a semiconductor memory device according to an embodiment of the present disclosure.

Referring to FIGS. 7A, 7B, and 8, in step S11, the first bonding structure BS1 including the peripheral circuit structure 110 may be formed. In step S21, the second bonding structure BS2 including the first memory cell array structure 130A may be formed. At this time, the second bonding structure BS2 may be formed on a first wafer (not shown). In step S31, the third bonding structure BS3′ including the second memory cell array structure 130B may be formed. At this time, the third bonding structure BS3′ may be formed on a second wafer (not shown). In step S41, the fourth bonding structure BS4 including the third memory cell array structure 130C may be formed. At this time, the fourth bonding structure BS4 may be formed on a fourth wafer.

As in step S40 described with reference to FIG. 6, in step S51, a bonding process for connecting the second bonding structure BS2 to the first bonding structure BS1 may be performed.

As in step S50 described with reference to FIG. 6, in step S61, a bonding process for connecting the third bonding structure BS3′ to the second bonding structure BS2 may be performed.

In step S71, a bonding process for connecting the fourth bonding structure BS4 to the third bonding structure BS3′ may be performed. At this time, the fourth bonding pad group 169C of the fourth bonding structure BS4 may be bonded to the third bonding pad group 169B of the third bonding structure BS3′. Thereafter, the fourth wafer may be removed to expose the third source layer 120C and the third pad pattern 120P23 of the fourth bonding structure BS4. As another example, the third source layer 120C and the third pad pattern 120P23 of the fourth bonding structure BS4 may be formed after removing the fourth wafer.

In step S81, the upper line array 210 may be formed on the fourth bonding structure BS4.

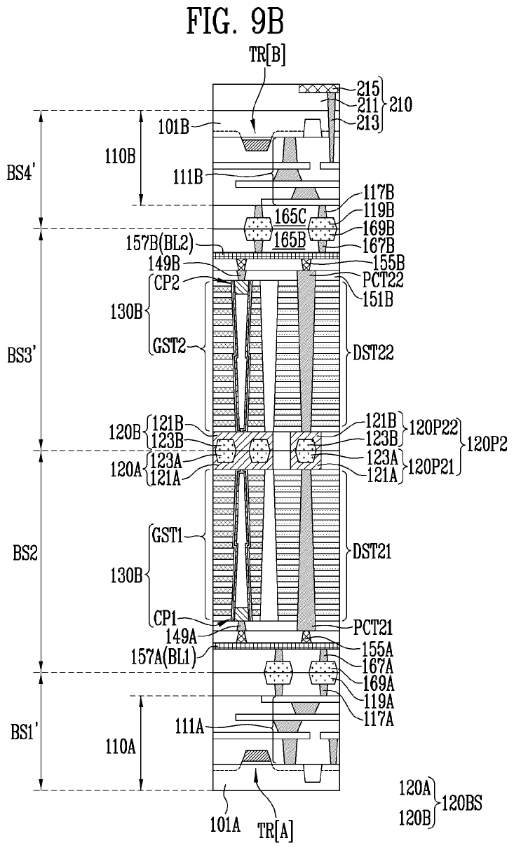

FIGS. 9A and 9B are diagrams illustrating a semiconductor memory device according to an embodiment of the present disclosure. FIG. 9A is a diagram illustrating a vertical arrangement of the semiconductor memory device, and FIG. 9B is a cross-sectional view of the semiconductor memory device shown in FIG. 9A. Hereinafter, a detailed description of configurations overlapping those described with reference to FIGS. 3A and 4A to 4D is omitted.

Referring to FIG. 9A, the semiconductor memory device may include a first peripheral circuit structure 110A, the plurality of first bit lines BL1, the first memory cell array structure 130A, the source bonding structure 120BS including the first source layer 120A and a second source layer 120B, the second memory cell array structure 130B, the plurality of second bit lines BL2, a second peripheral circuit structure 110B, and the upper line array 210.

The first peripheral circuit structure 110A may be disposed to be adjacent to the plurality of first bit lines BL1, and the second peripheral circuit structure 110B may be disposed to be adjacent to the plurality of second bit lines BL2. The upper line array 210 may overlap the plurality of second bit lines BL2 with the second peripheral circuit structure 110B interposed therebetween.

A plurality of transistors, a capacitor, a resistor, and the like configuring the peripheral circuit 40 shown in FIG. 1 may be distributed in the first peripheral circuit structure 110A and the second peripheral circuit structure 110B.

Referring to FIG. 9B, the semiconductor memory device may include a first bonding structure BS1′, the second bonding structure BS2 connected to the first bonding structure BS1′, the third bonding structure BS3′ connected to the second bonding structure BS2, a fourth bonding structure BS4′ connected to the third bonding structure BS3′, and the upper line array 210 adjacent to the fourth bonding structure BS4′.

The first bonding structure BS1′ may include the first peripheral circuit structure 110A, a first via group 117A, and a first bonding pad group 119A. The first peripheral circuit structure 110A may include a first group of transistor TR[A] and a first interconnection group 111A connected thereto. The first via group 117A may be connected to the first group of transistor TR[A] via the first interconnection group 111A. The first group of transistor TR[A] may be disposed on a side of a first semiconductor substrate 101A. The first bonding pad group 119A may be electrically connected to the first peripheral circuit structure 110A via the first via group 117A.

As described with reference to FIGS. 4A to 4D, the second bonding structure BS2 may include the second bonding pad group 169A, the second via group 167A, the first line array 157A including the first bit line BL1, the third via group 155A, the first memory cell array structure 130A including the first gate stack GST1 and the first cell plug CP1, the first bit line contact 149A, the first dummy insulating stack DST21, the first contact structure PCT21, the first source layer 120A, and the first pad pattern 120P21. As described with reference to FIG. 5A, each of the first source layer 120A and the first pad pattern 120P21 may include the first doped semiconductor layer 121A having the first groove and the first metal layer 123A buried in the first groove.

As described with reference to FIGS. 4A to 4D, the third bonding structure BS3′ may include the second source layer 120B, the second pad pattern 120P22, the second memory cell array structure 130B including the second gate stack GST2 and the second cell plug CP2, the second dummy insulating stack DST22, the second contact structure PCT22, the second bit line contact 149B, the fourth via group 155B, and the second line array 157B including the second bit line BL2. As described with reference to FIG. 7B, the third bonding structure BS3′ may further include the fifth via group 167B connected to the second line array 157B and the third bonding pad group 169B connected to the fifth via group 167B.

As described with reference to FIG. 5A, each of the second source layer 120B and the second pad pattern 120P22 may include the second doped semiconductor layer 121B having the second groove and the second metal layer 123B buried in the second groove. As described with reference to FIGS. 4A to 4D, the second source layer 120B may be bonded to the first source layer 120A to form the source bonding structure 120BS, and the second pad pattern 120P22 may be bonded to the first pad pattern 120P21 to form the pad bonding structure 120P2.

The fourth bonding structure BS4′ may include a fourth bonding pad group 119B, a sixth via group 117B, and the second peripheral circuit structure 110B. The second peripheral circuit structure 110B may include a second group of transistor TR[B] and a second interconnection group 111B connected thereto.

The fourth bonding pad group 119B may be bonded to the third bonding pad group 169B. The sixth via group 117B may be electrically connected to the second line array 157B via the fourth bonding pad group 119B and the third bonding pad group 169B. The second interconnection group 111B may be connected to the fourth bonding pad group 119B. The second group of transistor TR[B] may be electrically connected to the sixth via group 117B via the second interconnection group 111B. The second group of transistor TR[B] may be disposed on a side of a second semiconductor substrate 101B adjacent to the upper line array 210.

The upper line array 210 may include the plurality of upper conductive plugs 213 and the plurality of upper routing lines 215. The plurality of upper conductive plugs 213 and the plurality of upper routing lines 215 may be disposed in an upper insulating layer 211. The upper insulating layer 211 may overlap the second semiconductor substrate 101B. Some of the plurality of upper conductive plugs 213 may pass through the second semiconductor substrate 101B to be connected to the second interconnection group 111B.

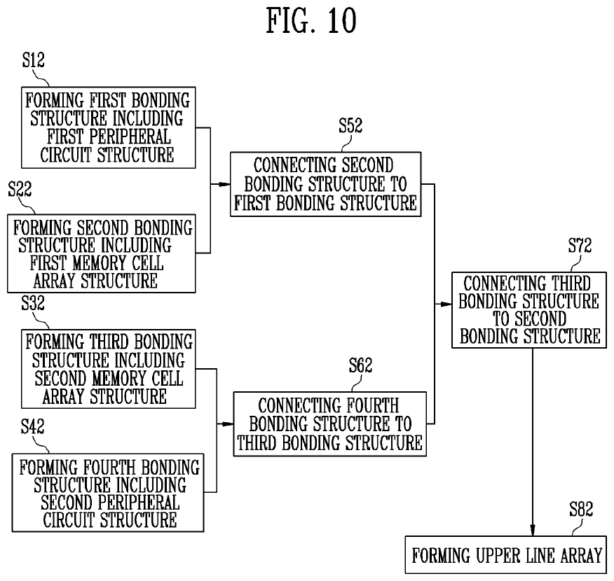

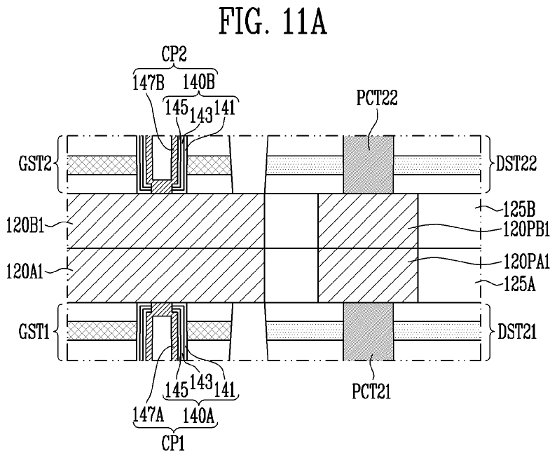

FIG. 10 is a flowchart illustrating a method of manufacturing a semiconductor memory device according to an embodiment of the present disclosure.

Referring to FIGS. 9A, 9B, and 10, in step S12, the first bonding structure BS1′ including the first peripheral circuit structure 110A may be formed. In step S22, the second bonding structure BS2 including the first memory cell array structure 130A may be formed. At this time, the second bonding structure BS2 may be formed on the first wafer (not shown). In step S32, the third bonding structure BS3′ including the second memory cell array structure 130B may be formed. At this time, the third bonding structure BS3′ may be formed on the second wafer (not shown). In step S42, the fourth bonding structure BS4′ including the second peripheral circuit structure 110B may be formed.

As in step S40 described with reference to FIG. 6, in step S52, a bonding process for connecting the second bonding structure BS2 to the first bonding structure BS1′ may be performed.

In step S62, a bonding process for connecting the fourth bonding structure BS4′ to the third bonding structure BS3′ may be performed. At this time, the third bonding pad group 169B of the third bonding structure BS3′ may be bonded to the fourth bonding pad group 119B of the fourth bonding structure BS4′. Thereafter, the second wafer may be removed to expose the second source layer 120B and the second pad pattern 120P22 of the third bonding structure BS3′. As another embodiment, the second source layer 120B and the second pad pattern 120P22 of the third bonding structure BS3′ may be formed after removing the second wafer.

In step S72, a bonding process for connecting the third bonding structure BS3′ to the second bonding structure BS2 may be performed. At this time, the second source layer 120B and the second pad pattern 120P22 of the third bonding structure BS3′ may be bonded to the first source layer 120A and the first pad pattern 120P21 of the second bonding structure BS2.

In step S82, the upper line array 210 may be formed on the fourth bonding structure BS4′.

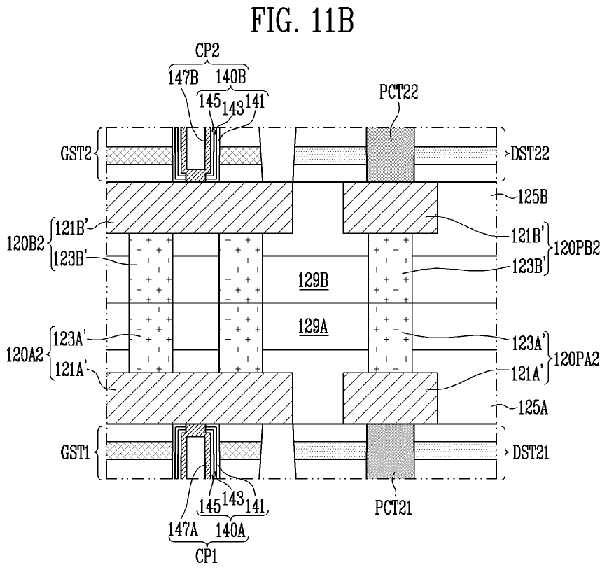

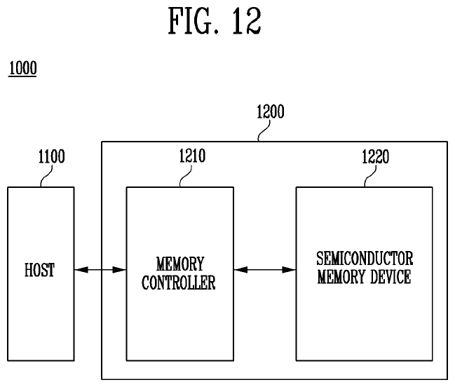

FIGS. 11A and 11B are cross-sectional views illustrating a source bonding structure and a pad bonding structure according to embodiments of the present disclosure.

Referring to FIGS. 11A and 11B, similarly to that described with reference to FIGS. 4A to 4D, the source bonding structure may include a first source layer 120A1 or 120A2 and a second source layer 120B1 or 120B2 between the first gate stack GST1 and the second gate stack GST2. Similarly, to that described with reference to FIGS. 4A to 4D, the pad bonding structure may include a first pad pattern 120PA1 or 120PA2 and a second pad pattern 120PB1 or 120PB2 between the first dummy insulating stack DST21 and the second dummy insulating stack DST22.

As described above in various embodiments of the present disclosure, the cell plug (for example, CP1 or CP2) disposed inside each gate stack (for example, GST1 or GST2) may include the channel layer (for example, 147A or 147B) and the memory layer (for example, 140A or 140B). The channel layer 147A or 147B may be formed of a semiconductor material that may serve as a channel area of a memory cell string. As an embodiment, the channel layer 147A or 147B may include silicon Si, germanium Ge, or a mixture thereof. The memory layer 140A or 140B may extend along a sidewall of the channel layer 147A or 147B. The memory layer 140A or 140B may include a blocking insulating layer 141, a data storage layer 143 between the blocking insulating layer 141 and the channel layer 147A or 147B, and a tunnel insulating layer 145 between the data storage layer 143 and the channel layer 147A or 147B. The blocking insulating layer 141 may include an insulating material capable of charge blocking. The tunnel insulating layer 145 may include an insulating material capable of charge tunneling. The blocking insulating layer 141 may include an insulating layer having a dielectric constant higher than that of the tunnel insulating layer 145. The data storage layer 143 may be formed of a material layer capable of storing changed data using Fowler Nordheim tunneling. As an embodiment, the data storage layer 143 may be formed of a charge trap insulating layer, a floating gate layer, or an insulating layer including a conductive nano dot. The charge trap insulating layer may include a silicon nitride layer. The present disclosure is not limited thereto, and the data storage layer 143 may be formed of a material layer capable of storing information based on an operation principle other than Fowler Nordheim tunneling. As an embodiment, the data storage layer 143 may include a phase change material layer, a ferroelectric layer, and the like.

As described above in various embodiments of the present disclosure, the contact structures PCT21 or PCT22 may be respectively disposed inside each of the dummy insulating stacks (for example, DST21 or DST22). One contact structure (for example, PCT21) may be electrically connected to another contact structure (for example, PCT22) via a pad bonding structure.

Referring to FIG. 11A, each of the source bonding structure and the pad bonding structure may be provided by bonding between the first doped semiconductor layer inside the first source level insulating layer 125A and the second doped semiconductor layer inside the second source level insulating layer 125B. Each of the first doped semiconductor layer and the second doped semiconductor layer may include at least one of an n-type impurity and a p-type impurity. As described above, the source bonding structure by the first source layer 120A1 and the second source layer 120B1 and the pad bonding structure by the first pad pattern 120PA1 and the second pad pattern 120PB1 may be provided by bonding between semiconductor layers without bonding between metal layers differently from the embodiment described with reference to FIGS. 4A to 4D. Compared to the embodiment shown in FIG. 11A, because, in an embodiment, the source bonding structure 120BS and the pad bonding structure 120P1 or 120P2 shown in FIGS. 4A to 4D have a low resistance, an operation characteristic of the semiconductor memory device may be improved.

Referring to FIG. 11B, each of the source bonding structure and the pad bonding structure may be provided by bonding between a first metal pattern 123A′ and a second metal pattern 123B′ disposed inside first and second intervening insulating layers 129A and 129B between the first source level insulating layer 125A and the second source level insulating layer 125B.

A first doped semiconductor layer 121A′ configuring a portion of each of the first source layer 120A2 and the first pad pattern 120PA2 may be formed in the first source level insulating layer 125A. A second doped semiconductor layer 121B′ configuring a portion of each of the second source layer 120B2 and the second pad pattern 120PB2 may be formed in the second source level insulating layer 125B.

The first intervening insulating layer 129A may be disposed to be adjacent to the first source level insulating layer 125A, and the second intervening insulating layer 129B may be disposed to be adjacent to the second source level insulating layer 125B. The first metal pattern 123A′ may extend from the first doped semiconductor layer 121A′ to pass through the first intervening insulating layer 129A, and configure another portion of each of the first source layer 120A2 and the first pad pattern 120PA2. The second metal pattern 123B′ may extend from the second doped semiconductor layer 121B′ to pass through the second intervening insulating layer 129B, and configure another portion of each of the second source layer 120B2 and the second pad pattern 120PB2. Apart from the embodiment shown in FIG. 11B, the source bonding structure 120BS and the pad bonding structure 120P1 or 120P2 shown in FIGS. 4A to 4D, in an embodiment, may be advantageous to miniaturization of the semiconductor memory device.

FIG. 12 is a block diagram illustrating an electronic system including a semiconductor memory device according to embodiments of the present disclosure.

Referring to FIG. 12, the electronic system 1000 may be a computing system, a medical device, a communication device, a wearable device, a memory system, and the like. The electronic system 1000 may include a host 1100 and a storage device 1200.

The host 1100 may store data in the storage device 1200 or read data stored in the storage device 1200 based on an interface. The interface may include at least one of a double data rate (DDR) interface, a universal serial bus (USB) interface, a multimedia card (MMC) interface, an embedded MMC (eMMC) interface, a peripheral component interconnection (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), integrated drive electronics (IDE) interface, a Firewire interface, a universal flash storage (UFS) interface, and a nonvolatile memory express (NVMe) interface.

The storage device 1200 may include a memory controller 1210 and a semiconductor memory device 1220. As an embodiment, the storage device 1200 may be a storage medium such as a solid state drive (SSD) or a USB memory.

The memory controller 1210 may store data in the semiconductor memory device 1220 or read data stored in the semiconductor memory device 1220 under control of the host 1100.

The semiconductor memory device 1220 may include one memory chip or a plurality of memory chips. The semiconductor memory device 1220 may store data or output stored data under control of the memory controller 1210.

The semiconductor memory device 1220 may be a nonvolatile memory device. The semiconductor memory device 1220 may include the structure described with reference to FIGS. 3A, 3B, 4A to 4D, and 5A and 5B, include the structure described with reference to FIGS. 7A and 7B, or include the structure described with reference to FIGS. 9A and 9B. A source bonding structure and a pad bonding structure of the semiconductor memory device 1220 may be replaced with the structures described with reference to FIGS. 11A and 11B. As an embodiment, the semiconductor memory device 1220 may include a source bonding structure including a first source layer and a second source layer bonded to each other, a first memory cell array structure connected to the first source layer of the source bonding structure, and a second memory cell array structure connected to the second source layer of the source bonding structure. The source bonding structure of the semiconductor memory device 1220 may include at least one of a semiconductor bonding area and a metal bonding area.

According to an embodiment of the present disclosure, because the first and second memory cell array structures may be bonded through the source bonding structure, the number of stacked memory cells of the semiconductor memory device may be increased. According to an embodiment of the present disclosure, an integration degree of the semiconductor memory device may be improved.

What is claimed is:

1. A semiconductor memory device comprising:
a source bonding structure including a first source layer and a second source layer bonded to each other;
a first memory cell array structure connected to the first source layer of the source bonding structure; and
a second memory cell array structure connected to the second source layer of the source bonding structure,
wherein the source bonding structure includes a semiconductor bonding area and a metal bonding area.

2. The semiconductor memory device of claim 1, wherein each of the first source layer and the second source layer includes a doped semiconductor layer forming the semiconductor bonding area of the source bonding structure and a metal layer forming the metal bonding area of the source bonding structure, and
wherein the metal layer is buried in a groove in the doped semiconductor layer.

3. The semiconductor memory device of claim 2, wherein the metal layer is formed of a material having a resistivity lower than that of the doped semiconductor layer.

4. The semiconductor memory device of claim 2, wherein the doped semiconductor layer includes doped silicon including at least one of an n-type impurity and a p-type impurity.

5. The semiconductor memory device of claim 1, wherein the first memory cell array structure comprises:
a first gate stack including a plurality of first conductive patterns stacked to be spaced apart in a first direction, the first gate stack adjacent to the first source layer;
a first channel layer connected to the first source layer and extending into the first gate stack; and
a first memory layer between the first channel layer and the first gate stack, and
the second memory cell array structure comprises:
a second gate stack including a plurality of second conductive patterns stacked to be spaced apart in a second direction opposite to the first direction, the second gate stack adjacent to the second source layer;
a second channel layer connected to the second source layer and extending into the second gate stack; and
a second memory layer between the second channel layer and the second gate stack.

6. The semiconductor memory device of claim 1, further comprising:
a first bit line overlapping the source bonding structure with the first memory cell array structure interposed between the first bit line and the source bonding structure;
a second bit line overlapping the source bonding structure with the second memory cell array structure interposed between the second bit line and the source bonding structure; and
a peripheral circuit structure disposed to be adjacent to the first bit line.

7. The semiconductor memory device of claim 6, further comprising:
a pad bonding structure disposed at a level where the source bonding structure is disposed and including a first pad pattern and a second pad pattern bonded to each other;
a first dummy insulating stack between the pad bonding structure and the peripheral circuit structure;
a second dummy insulating stack overlapping the first dummy insulating stack with the pad bonding structure interposed between the first dummy insulating stack and the second dummy insulating stack;
a first contact structure connected to the first bit line and the first pad pattern and passing through the first dummy insulating stack; and
a second contact structure connected to the second bit line and the second pad pattern and passing through the second dummy insulating stack.

8. The semiconductor memory device of claim 7, wherein the pad bonding structure includes a semiconductor bonding area and a metal bonding area, and
wherein the peripheral circuit structure includes a transistor connected to the first bit line.

9. The semiconductor memory device of claim 6, further comprising:
a first dummy insulating stack disposed between the peripheral circuit structure and the first source layer;
a second dummy insulating stack overlapping the first dummy insulating stack with the source bonding structure interposed between the first dummy insulating stack and the second dummy insulating stack;
a first contact structure connected to the source bonding structure and passing through the first dummy insulating stack; and
a second contact structure connected to the source bonding structure and passing through the second dummy insulating stack.

10. The semiconductor memory device of claim 9, wherein the peripheral circuit structure includes a transistor connected to the first contact structure.

11. The semiconductor memory device of claim 1, wherein the metal bonding area is formed in a mesh shape structure.

12. The semiconductor memory device of claim 1, further comprising:
a first bit line overlapping the source bonding structure with the first memory cell array structure interposed between the source bonding structure and the first bit line;
a second bit line overlapping the source bonding structure with the second memory cell array structure interposed between the source bonding structure and the second bit line;
a third bit line overlapping the second bit line;
a bit line bonding structure disposed between the second bit line and the third bit line and connecting the third bit line to the second bit line;
a third source layer overlapping the second memory cell array structure with the second bit line and the third bit line interposed between the second memory cell array structure and the third source layer; and
a third memory cell array structure between the third bit line and the third source layer.

13. The semiconductor memory device of claim 12, further comprising:
a peripheral circuit structure disposed to be adjacent to the first bit line and including a transistor connected to the first bit line;
a pad bonding structure disposed at a level where the source bonding structure is disposed and including a first pad pattern and a second pad pattern bonded to each other;
a first dummy insulating stack between the pad bonding structure and the peripheral circuit structure;
a second dummy insulating stack overlapping the first dummy insulating stack with the pad bonding structure interposed therebetween;
a third dummy insulating stack overlapping the second dummy insulating stack with the bit line bonding structure interposed between the second dummy insulating stack and the third dummy insulating stack;
a first contact structure connected to the first bit line and the first pad pattern and passing through the first dummy insulating stack;
a second contact structure connected to the second bit line and the second pad pattern and passing through the second dummy insulating stack; and
a third contact structure passing through the third dummy insulating stack.

14. The semiconductor memory device of claim 1, further comprising:
a first bit line overlapping the source bonding structure with the first memory cell array structure interposed between the source bonding structure and the first bit line;
a second bit line overlapping the source bonding structure with the second memory cell array structure interposed between the source bonding structure and the second bit line;
a first peripheral circuit structure adjacent to the first bit line; and
a second peripheral circuit structure adjacent to the second bit line.
